(19) United States
(12) Patent Application Publication
(10) Pub. No.: US 2008/0303153 A1
(43) Pub. Date: Dec. 11, 2008

(54) SEMICONDUCTOR DEVICE, MANUFACTURING METHOD THEREOF, AND SEMICONDUCTOR DEVICE PRODUCT

(75) Inventors: Kiyoshi Oi, Nagano-shi (JP); Toru Hizume, Nagano-shi (JP); Teruaki Chino, Nagano-shi (JP)

Correspondence Address: RANKIN, HILL & CLARK LLP, 38210 Glenn Avenue, WILLOUGHBY, OH, 44094-7808, US

(73) Assignee: SHINKO ELECTRIC INDUSTRIES CO., LTD., Nagano-shi (JP)

(21) Appl. No.: 12/134,668

(22) Filed: Jun. 6, 2008

(30) Foreign Application Priority Data
Jun. 11, 2007 (JP) 2007-154126

(51) Int. Cl. H01L 23/488; H01L 21/56

(52) U.S. Cl. 257/738; 438/127; 257/E21.502; 257/E23.023

(57) ABSTRACT

In a semiconductor device, a semiconductor element is built into a resin molded part molded in a flat plate shape. A wiring is electrically connected to the semiconductor element and is disposed on one surface of the resin molded part so that an inner surface side of the wiring is sealed with the resin molded part and an outer surface of the wiring is exposed flush with the one surface of the resin molded part. An electrode is disposed on the wiring in an outside of a plane area of the semiconductor element and extends through the resin molded part in a thickness direction. A tip part of the electrode protrudes from the other surface of the resin molded part.

This application claims priority to Japanese Patent Application No. 2007-154126, filed Jun. 11, 2007, in the Japanese Patent Office. The Japanese Patent Application No. 2007-154126 is incorporated by reference in its entirety.

### TECHNICAL FIELD

The present disclosure relates to a semiconductor device and a manufacturing method thereof, and a semiconductor device product. More specifically, the present disclosure relates to a semiconductor device in which a semiconductor element is built into a body made of a resin molded part, a manufacturing method of the semiconductor device, and a semiconductor device product including the semiconductor devices.

### RELATED ART

There are semiconductor device products in which semiconductor elements or semiconductor devices are stacked and mounted for the purpose of composition and density growth of the semiconductor device. For example, there are a product of a semiconductor device in which plural semiconductor elements are stacked on a wiring substrate and each of the semiconductor elements is electrically connected to the wiring substrate, a product in which semiconductor elements are stacked and mounted and are mutually electrically connected and mounted, a product in which plural semiconductor devices in which semiconductor elements are mounted are stacked, etc.

In a semiconductor device product formed by stacking semiconductor devices, the semiconductor devices are bonded through a conductive material such as a solder ball and thereby space between the devices is obtained and also the semiconductor devices of upper and lower sides are electrically connected.

Semiconductor devices of various forms can be used in a stack type semiconductor device. A semiconductor device (for example, see Patent References 1 and 2) in which the whole shape is formed in a flat plate body and a semiconductor element is built in the flat plate body is effectively used as a method for thinning the whole semiconductor device.

[Patent Reference 1] Japanese Patent Application Publication No. 2006-196785

[Patent Reference 2] Japanese Patent Application Publication No. 2007-27526

The semiconductor device described in Patent References 1 and 2 is formed by building a semiconductor element into a body formed in a thin flat plate shape and exposing electrodes electrically connected to the semiconductor element to both surfaces of a thickness direction of the body. Therefore, it is necessary to bond the electrodes exposed to the outside of the semiconductor device using a conductive material such as solder in the case of stacking these semiconductor devices and assembling a semiconductor device product.

The semiconductor device formed by forming the whole shape in a flat plate shape and exposing the electrodes to both surfaces has advantages that thinning is facilitated and the semiconductor device can be formed compactly even in the case of stacking plural semiconductor devices. However, more effective use can be made by facilitating electrical connection between the semiconductor devices in the case of stacking the semiconductor devices.

### SUMMARY

Exemplary embodiments of the present invention provide a semiconductor device capable of easily assembling a semiconductor device product and easily miniaturizing the semiconductor device product in the case of stacking semiconductor devices and manufacturing the semiconductor device product, a manufacturing method of the semiconductor device, and a semiconductor device product including the semiconductor devices.

A semiconductor device according to the present invention comprises a resin molded part molded in a flat plate shape; a semiconductor element built into the resin molded part; a wiring, which is electrically connected to the semiconductor element and is disposed on one surface of the resin molded part so that an inner surface side of the wiring is sealed with the resin molded part and an outer surface of the wiring is exposed flush with the one surface of the resin molded part; and an electrode, which is disposed on the wiring in an outside of a plane area of the semiconductor element and extends through the resin molded part in a thickness direction, the electrode having a tip part which protrudes from the other surface of the resin molded part.

Also, the semiconductor element is electrically connected to the wiring by flip chip bonding, and aback surface of the semiconductor element is exposed flush with the other surface of the resin molded part. Therefore, it is provided as a semiconductor device which has good heat dissipation and is formed compactly in a thin shape.

Also, the semiconductor element is electrically connected to the wiring by flip chip bonding, and the electrode is arranged in a lead end of the wiring led from an inside of the plane area of the semiconductor element to the outside. Therefore, a semiconductor device is formed compactly and it is provided as a semiconductor device capable of easily assembling a stack type semiconductor device.

Also, the semiconductor element is electrically connected to the wiring by wire bonding.

Also, a plurality of the semiconductor elements are stacked and built into the resin molded part. Therefore, the semiconductor device with higher density is provided as a semiconductor device.

Also, forms in which the electrode is formed as a ball bump formed by a ball bonding method and also the ball bumps are formed with the ball bumps stacked and also the electrode is formed on the wiring with the electrode plated in a post shape and also the electrode is formed by folding a metal wire in a chevron-shaped loop shape by a wire bonding method and also the electrode is formed by bonding a conductive ball body to the wiring can be used.

Also, a bump is disposed in the semiconductor element built into the resin molded part and protrudes from the other surface of the resin molded part. Therefore, electrical connection through the bumps disposed in the semiconductor elements can be achieved in the case of stacking the semiconductor devices.

Also, in a semiconductor device product, the semiconductor devices are stacked in the same direction and are integrated and wiring of one semiconductor device of adjacent devices makes contact with a tip part of an electrode of the other semiconductor device of the adjacent devices and electrical continuity between the devices is achieved. By electrodes disposed in the semiconductor devices, the electrical continuity between the devices of the semiconductor devices is achieved and a stack type semiconductor device can be assembled easily.

Also, in a semiconductor device product, the semiconductor devices are stacked in a direction of opposing tip parts of the electrodes of the adjacent devices and are integrated and the tip parts of the electrodes are mutually abutted and electrical continuity between the semiconductor devices is achieved.

Also, in a semiconductor device product, the semiconductor devices each having a bump, which is disposed in the semiconductor element built into the resin molded part and protrudes from the other surface of the resin molded part, are stacked in the same direction and are integrated and wiring of one semiconductor device of adjacent devices makes contact with a tip part of the other semiconductor device of the adjacent devices and electrical continuity between the semiconductor devices is achieved and also electrical continuity between the devices through the bumps is achieved through the semiconductor elements.

Also, a manufacturing method of a semiconductor device, comprises steps of: forming a wiring on a metal substrate in a predetermined pattern; mounting a semiconductor element on the metal substrate and electrically connecting the semiconductor element to the wiring; forming an electrode on the wiring; molding a resin by a resin molding metal mold having a cavity, which accommodates the semiconductor element, the wiring and the electrode, by filling the cavity with the resin and sealing the semiconductor element, the wiring and the electrode with the resin; and removing only the metal substrate after the resin is molded, wherein when the resin is molded by the resin molding metal mold, an inner surface of the cavity is covered with a film for resin molding and the cavity is filled with the resin in a state of sinking a tip part of the electrode in the film and the resin is molded without attaching the resin to the tip part.

Also, when a resin is molded by the resin molding metal mold, an inner surface of the cavity is covered with a film for resin molding and the cavity is filled with a resin in a state of sinking a tip part of the electrode in the film and bringing the film into pressure contact with a back surface of the semiconductor element and the resin is molded without attaching the resin to the tip part and the back surface of the semiconductor element.

Also, an outer surface of the wiring can be exposed flush with one outer surface of the resin molded part by selectively chemically dissolving and removing only the metal substrate without eroding the wiring when the metal substrate is removed after the resin is molded.

A semiconductor device according to the invention is constructed so that a semiconductor element is built into a resin molded part and also an outer surface of wiring is exposed to one surface of the resin molded part and a tip part of an electrode is protruded from the other surface. Therefore, the semiconductor device itself can be formed compactly in a thin shape and also electrical continuity between the semiconductor devices is obtained easily and surely by aligning and stacking the semiconductor devices and assembly can be performed. Also, according to a manufacturing method of the semiconductor device according to the invention, an inner surface of a cavity of a resin molding metal mold is covered with a film and a tip part of an electrode is sunk in the film and a resin is molded. Therefore, the semiconductor device can be manufactured so that the tip part of the electrode is protruded from an outer surface of the resin molded part and the resin is not attached to an outer surface of the tip part.

Other features and advantages maybe apparent from the following detailed description, the accompanying drawings and the claims.

### BRIEF DESCRIPTION OF THE DRAWINGS

FIG. 1A is a sectional view showing a configuration of a first embodiment of a semiconductor device according to the invention.

FIG. 1B is a plan view showing a configuration of the first embodiment of the semiconductor device.

FIGS. 2A to 2F are explanatory views showing a manufacturing step of the semiconductor device of the first embodiment.

FIG. 3 is a sectional view showing a modified example of the semiconductor device of the first embodiment.

FIG. 4A is a sectional view showing another modified example of the semiconductor device of the first embodiment.

FIG. 4B is an explanatory view showing a manufacturing method of the semiconductor device in FIG. 4A.

FIGS. 5A to 5D are explanatory views showing a configuration of a second embodiment of a semiconductor device and its manufacturing step.

FIGS. 6A to 6D are explanatory views showing a configuration of a third embodiment of a semiconductor device and its manufacturing step.

FIGS. 7A to 7D are explanatory views showing a configuration of a fourth embodiment of a semiconductor device and its manufacturing step.

FIGS. 8A and 8B are explanatory views showing a configuration of a fifth embodiment of a semiconductor device and its manufacturing step.

FIGS. 9A and 9B are explanatory views showing a configuration of a sixth embodiment of a semiconductor device and its manufacturing step.

FIGS. 10A and 10B are explanatory views showing a configuration of a seventh embodiment of a semiconductor device and its manufacturing step.

FIGS. 11A to 11C are sectional views showing an example assembled by stacking semiconductor devices.

FIGS. 12A and 12B are sectional views showing an example assembled by stacking semiconductor devices.

### DETAILED DESCRIPTION

A preferred embodiment of the invention will hereinafter be described in detail with reference to the accompanying drawings.

### First Embodiment

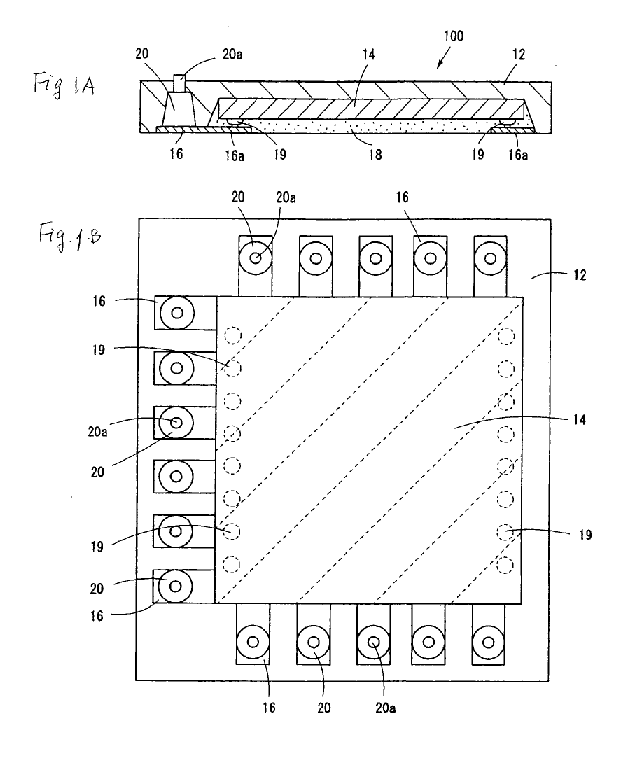

FIG. 1A is a plan view showing a configuration of a first embodiment of a semiconductor device according to the invention. FIG. 1B is a plan view showing a configuration of the first embodiment of the semiconductor device. A semiconductor device 100 of the present embodiment is formed by sealing a semiconductor element 14 inside a resin molded part 12 molded in a flat plate shape. On a lower surface which is one surface of the resin molded part 12, an inner surface side of wiring 16 electrically connected to the semiconductor element 14 is sealed with the resin molded part 12 and an outer surface of the wiring 16 is exposed flush with an outer surface of the resin molded part 12.

The semiconductor element 14 is connected to an electrode 16a for connection formed on the wiring 16 by flip chip bonding, and a lower surface of the semiconductor element 14 and the portion of bonding between the semiconductor element 14 and the electrode 16a are sealed with an underfill resin 18. An outer surface of the underfill resin 18 is also formed flush with the outer surface of the resin molded part 12 and the lower surface of the semiconductor element 14 becomes a flat surface as a whole.

One end of the wiring 16 is formed in the electrode 16a to which a bump 19 of the semiconductor element 14, and the other end of the wiring 16 is formed in a shape led from a plane area of the semiconductor element 14 to the outside, the so-called fan-out shape. An electrode 20 is attached in a form erected on the wiring 16 in a lead position of the wiring 16 led from the plane area of the semiconductor element 14 to the outside.

The electrode 20 extends through the resin molded part 12 in a thickness direction and a tip part 20a of the electrode 20 is protruded in a state of being exposed from an upper surface which is the other surface of the resin molded part 12 as shown in the drawing.

In the semiconductor device 100 of the embodiment, the wirings 16 are formed from the plane area of the semiconductor element 14 in a form in which the wirings 16 are led from three sides of the semiconductor element 14 to the outside as shown in FIG. 1B. The electrode 20 is formed in alignment with the lead end of each of the wirings 16.

In addition, the wirings 16 can be arranged in any pattern, and can be arranged so as to be led from each side of the semiconductor element 14, one side or two sides of the semiconductor element 14 in addition to being led from three sides of the semiconductor element 14 as described in the embodiment.

In the semiconductor device 100 of the embodiment, the electrode 20 is formed by a ball bump. When the electrode 20 is formed by the ball bump, a method of ball bonding using a gold wire can be used. According to this method, the gold wire is melted in a ball shape and is bonded on the wiring 16 and the gold wire is pulled upward and is cut in a predetermined height position. Therefore, the electrode 20 can be formed in a necessary height and can be formed in a form in which the tip part 20a protrudes linearly. The method for forming the electrode 20 by the ball bonding has advantages that the height of the electrode 20 can be ensured by selecting a thickness of the gold wire and also the electrode 20 can be formed simply.

### (Manufacturing Method of Semiconductor Device)

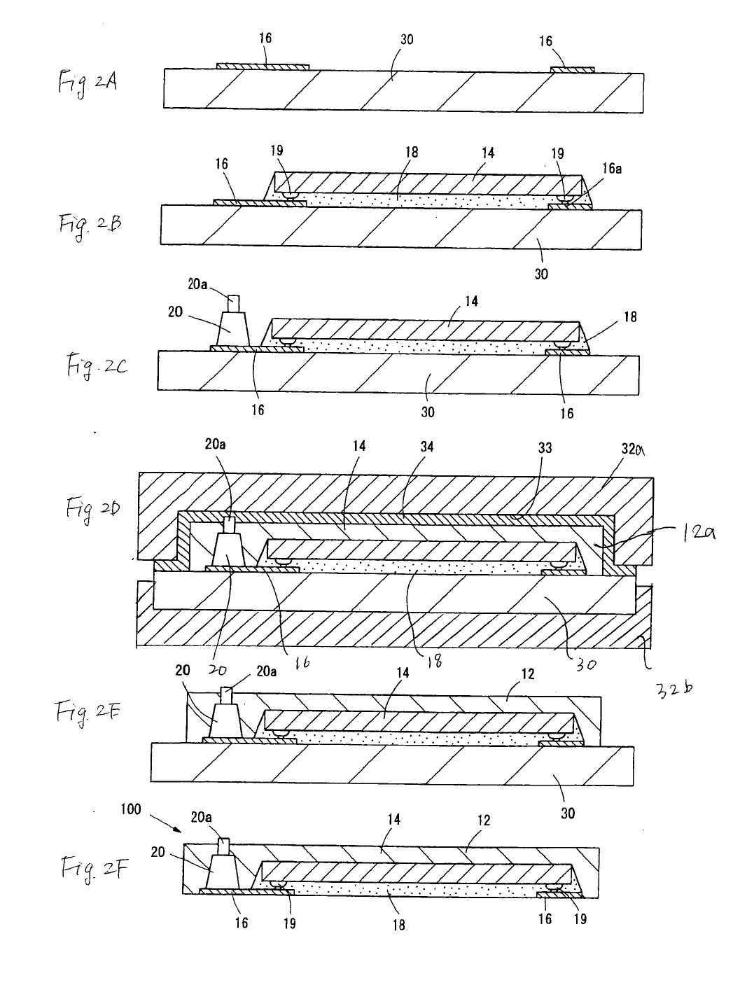

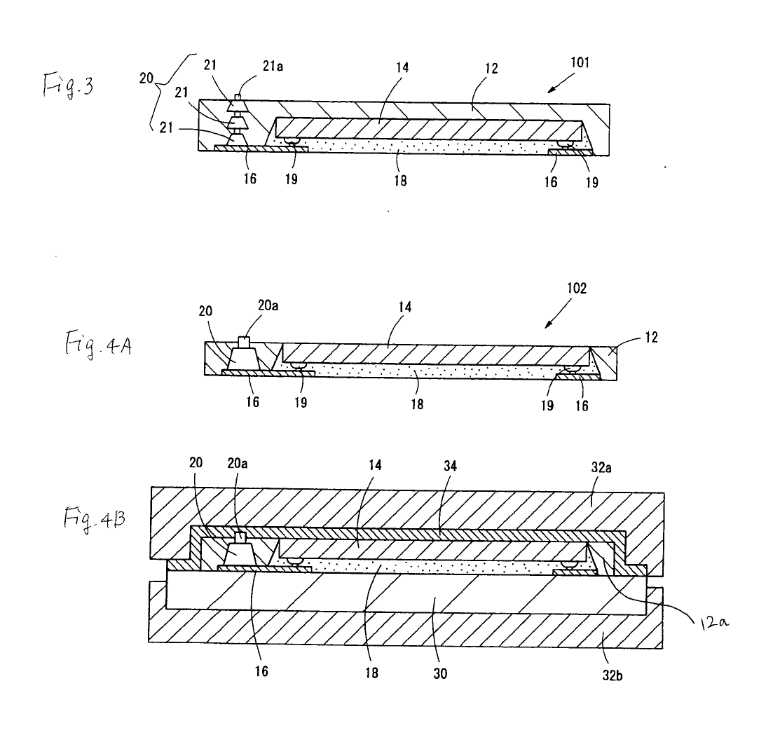

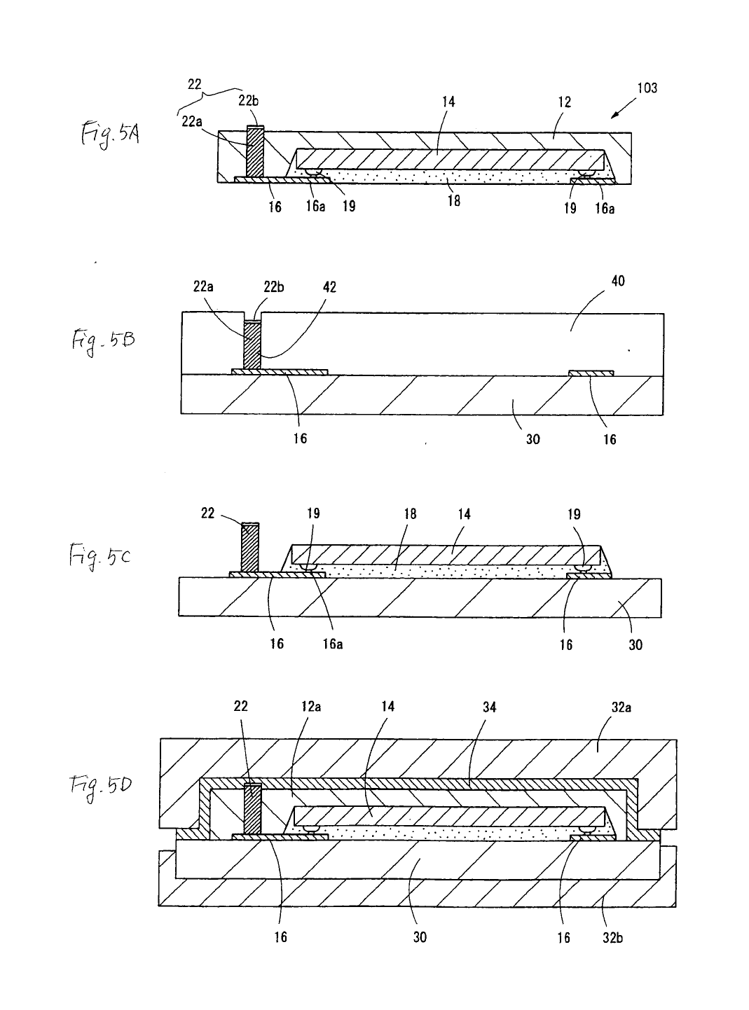

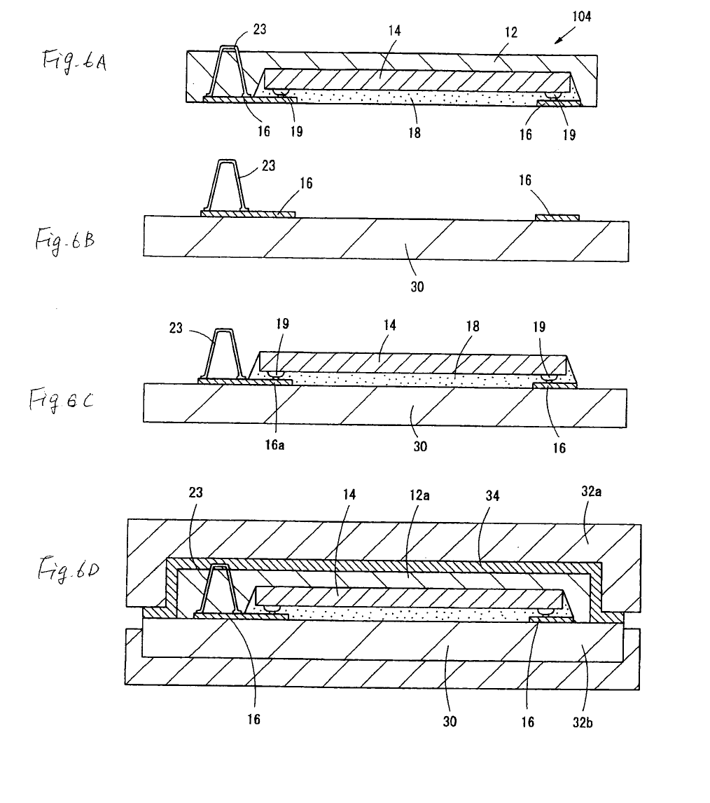

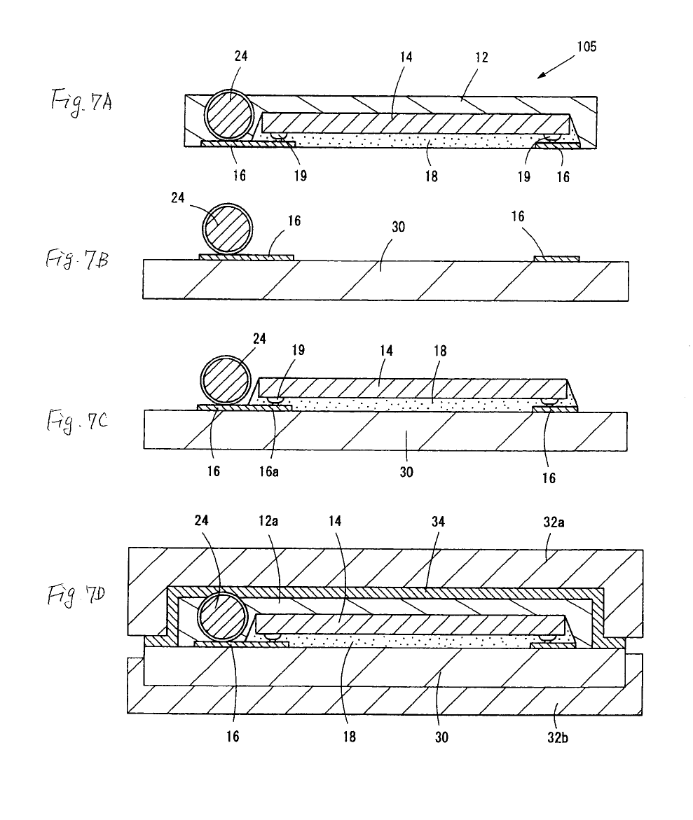

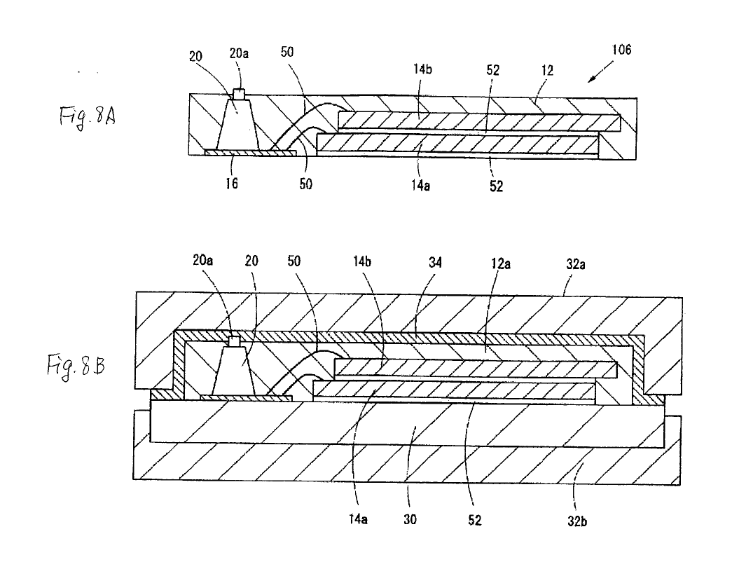

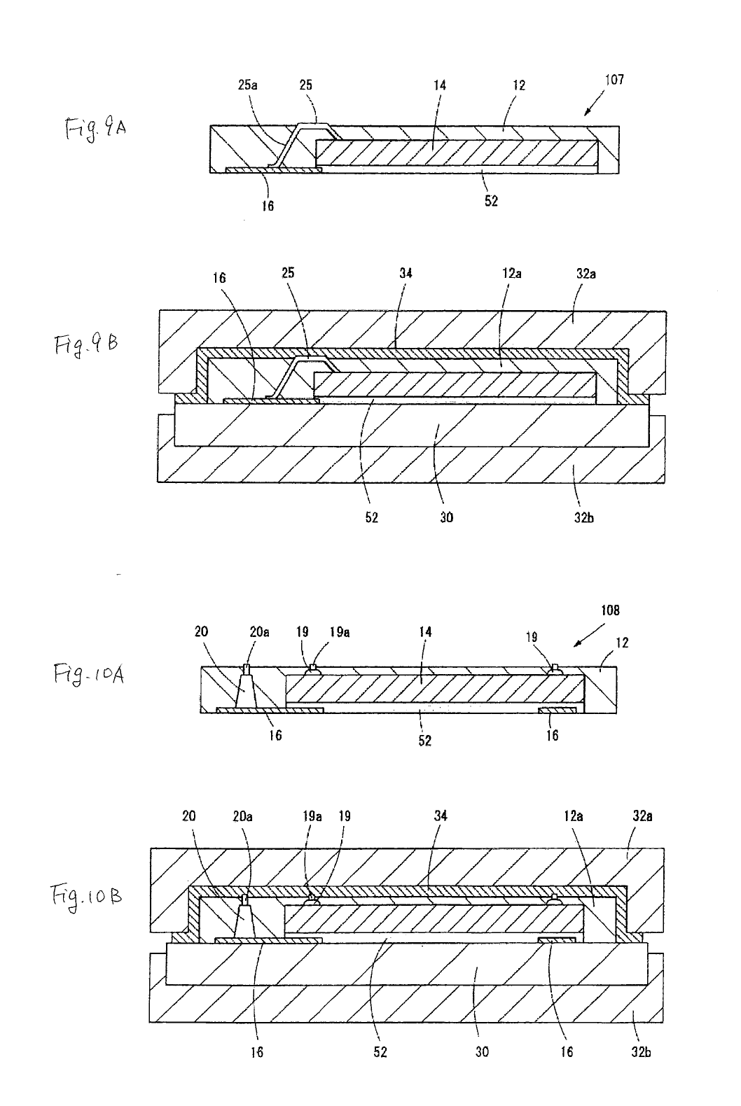

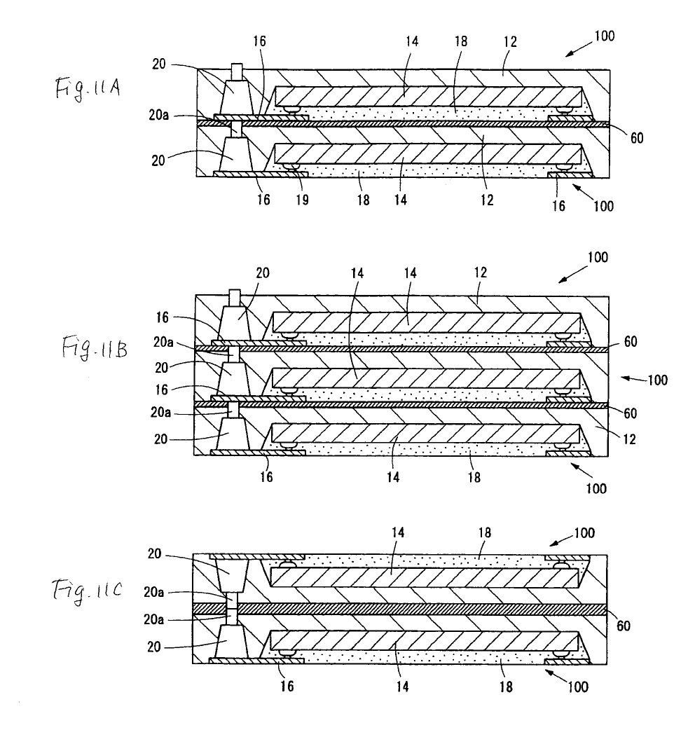

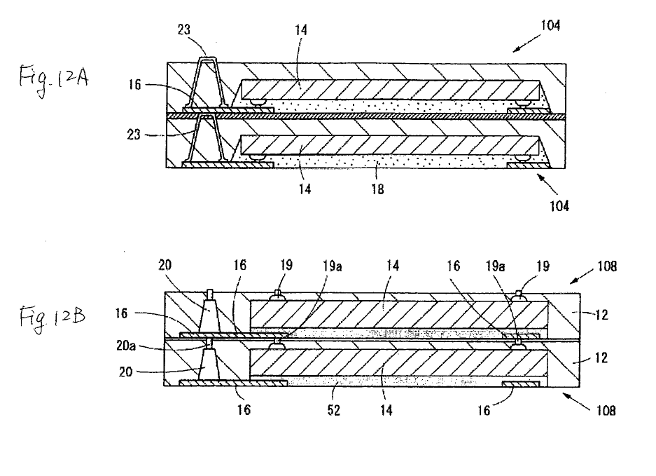

FIGS. 2A to 2F show a manufacturing step of the semiconductor device 100 of the embodiment described above.

FIG. 2A shows a state of forming wirings 16 on a surface of a metal substrate 30 in a predetermined pattern. The metal substrate 30 is used as a support body for forming the wirings 16, and is chemically dissolved and removed in a post-step. Therefore, as a metal substrate material, metals in which the metal substrate 30 is selectively removed without eroding the wirings 16, for example, copper or stainless steel in the case of forming an electrode 20 by a gold wire are used.

In the case of forming the wiring 16 in a predetermined pattern, a surface of the metal substrate 30 is coated with a plating resist and the plating resist is subject to light exposure and development operations to expose a region for forming the wiring 16. Then, plating is deposited inside an exposed recessed part by electrolytic plating. The wiring 16 is formed by performing, for example, gold plating/nickel plating/gold plating from the lower layer side in consideration of properties of bonding between the wiring 16 and a bump 19 of a semiconductor element 14 and a situation in which an outer surface of the wiring 16 is exposed to an outer surface of a resin molded part 12 of the semiconductor device 100. A thickness of the wiring 16 is about 0.125 mm as an example.

After the wirings 16 are formed on the surface of the metal substrate 30, the semiconductor element 14 is aligned with electrodes 16a formed on the wirings 16 and is mounted. In the embodiment, after the semiconductor element 14 is mounted by flip chip bonding and the bumps 19 of the semiconductor element 14 are bonded to the electrodes 16a, the portion of bonding between the bumps 19 and the electrode 16a and the portion of a gap between the semiconductor element 14 and the metal substrate 30 are filled with an underfill resin 18 (FIG. 2B). The underfill resin 18 adheres to the side edge of the semiconductor element 14 in a meniscus shape and a lower surface and a side surface of the semiconductor element 14 are sealed.

When the bump 19 of the semiconductor element 14 is a solder bump in the case of making flip chip bonding between the semiconductor element 14 and the metal substrate 30, bonding can be performed as it is. When the bump 19 is a ball bump, bonding is performed after solder is previously deposited on the electrode 16a. Also, other methods of bonding using an anisotropic conductive film can be used in addition to bonding the bump 19 to the electrode 16a by solder. Also, the semiconductor element 14 can be mounted by wire bonding rather than by the flip chip bonding.

Next, an electrode 20 is formed on the wiring 16 led from a plane area of the semiconductor element 14 to the outside. FIG. 2C shows a state of forming the electrode 20 on the wiring 16.

As described above, the electrode 20 is formed by a ball bonding method using a metal wire such as a gold wire. A bonding condition is set so that a cut position of the gold wire is defined and the electrode 20 becomes a predetermined height when the electrode 20 is formed by the ball bonding. In the case by the ball bonding, the gold wire is cut in a state of pulling up the gold wire, so that the tip part 20a of the electrode 20 becomes linear.

When a thickness of the semiconductor element 14 is about 0.100 mm, a height of the electrode 20 is about 0.150 mm.

In addition, a step of forming the electrode 20 can be replaced with a step of mounting the semiconductor element 14 on the metal substrate 30 backward and forward.

After the semiconductor element 14 is mounted on the metal substrate 30 and the electrode 20 is formed, the semiconductor element 14 is molded by a resin. FIG. 2D shows a state of resin molding using resin molding metal molds 32a, 32b. A cavity 33 for accommodating the semiconductor element 14, the wiring 16 and the electrode 20 and molding an outer shape in a flat plate body by a resin is formed in the resin molding metal mold 32a. A film 34 for resin molding is deposited on an inner surface of this cavity 33 to mold the resin.

The film 34 for resin molding has flexibility in which the tip part 20a of the electrode 20 can sink, and a film material with a thickness thicker than a depth in which the tip part 20a sinks is used. When the metal substrate 30 is clamped by the resin molding metal molds 32a, 32b, the tip part 20a sinks in the film 34 and a resin can be molded without attaching a resin 12a to an outer surface of the tip part 20a.

When the thickness of the semiconductor element 14 is set at 0.1 mm and the height of the electrode 20 is set at 0.15 mm, a depth dimension of the cavity 33 formed in the resin molding metal mold 32a could be set so that a resin thickness in the rear of the semiconductor element 14 becomes about 0.125 mm.

FIG. 2E shows a state after the resin is molded. The tip part 20a of the electrode 20 is exposed to an outer surface of the resin molded part 12 formed by curing the resin 12a.

A semiconductor device 100 shown in FIG. 2F is obtained by dissolving and removing the metal substrate 30 after the resin is molded. Only the metal substrate 30 can be selectively dissolved and removed without dissolving the wiring 16 made of, for example, gold plating/nickel plating/gold plating by using a cupric chloride solution in the case of using a copper plate as the metal substrate 30.

The semiconductor device 100 in which an outer surface of the wiring 16 is exposed flush with the outer surface of the resin molded part 12 and an outer surface of the underfill resin 18 is also flush with the outer surface of the wiring 16 is obtained by dissolving and removing the metal substrate 30.

As described above, the metal substrate 30 is used as a support body for supporting the wiring 16 and is finally dissolved and removed. Therefore, it is preferable to use metals with a sufficient difference between etching rates or without eroding the wiring 16 by an etching solution for dissolving the metal substrate 30 as combination of metal materials used in the wiring 16 and the metal substrate 30. Since the metal substrate 30 could use a substrate with a thickness only having action as the support body of the wiring 16, processing for dissolving and removing the metal substrate 30 in a post-step can also be performed simply.

In addition, the manufacturing step of the single semiconductor device 100 is shown in FIGS. 2A to 2F, but in an actual production step, a method, in which a large-sized metal substrate 30 for multiple pieces is used and wiring 16 is formed on this metal substrate 30 according to predetermined pattern and array and a semiconductor element 14 is mounted every a formation area of each semiconductor device and a resin is molded and then the metal substrate 30 is finally cut from large-sized work to each individual semiconductor device 100, could be used.

### Modified Example

FIGS. 3 and 4A, 4B show modified examples of a semiconductor device obtained by forming an electrode 20 using the ball bonding method described above.

A semiconductor device 101 shown in FIG. 3 is an example formed by stacking ball bumps 21 in the case of forming an electrode 20 by ball bonding.

There are cases where the electrode 20 with a sufficient height cannot be formed by one ball bonding when ball bonding is performed using a relatively thin gold wire or when it is necessary to increase a height of the electrode 20 since a thickness of a semiconductor element 14 is thick. In such cases, the necessary height of the electrode 20 can be ensured by stacking the ball bumps 21.

The example shown in FIG. 3 is an example in which the three ball bumps 21 are stacked, but the number of the ball bumps 21 to be stacked is not particularly limited. Also, a wire used in the ball bonding is not limited to the gold wire, and other metal wires such as an aluminum wire can be used.

A semiconductor device 102 shown in FIG. 4A is an example formed by exposing a back surface of a semiconductor element 14 to an outer surface of a resin molded part 12. In order to expose the back surface of the semiconductor element 14 to the outer surface of the resin molded part 12 thus, in the case of clamping work by resin molding metal molds 32a, 32b, a resin is molded so that a tip part 20a of an electrode 20 is sunk in a film 34 for resin molding and also the film 34 is brought into pressure contact with the back surface of the semiconductor element 14 as shown in FIG. 4B. The tip part 20a of the electrode 20 and the back surface of the semiconductor element 14 are covered with the film 34. Therefore, a resin 12a does not adhere to these surfaces and the resin is molded.

In the semiconductor device 100 shown in FIG. 1A, a back surface of the semiconductor element 14 is covered with the resin molded part 12 and the semiconductor element 14 is protected by the resin molded part 12. Therefore, there is an advantage of improving shape retention of the semiconductor device 100 as compared with the case of exposing the back surface of the semiconductor element 14.

On the other hand, the semiconductor device 102 shown in FIG. 4A has an advantage that heat dissipation from the semiconductor device 100 improves since the back surface of the semiconductor element 14 is exposed to the outer surface of the resin molded part 12. The semiconductor device 102 also has an advantage that a thickness of the whole semiconductor device 102 becomes thin and the semiconductor device can be formed compactly since the back surface of the semiconductor element 14 is not covered with a resin.

### Second Embodiment

FIGS. 5A to 5D show a configuration of a second embodiment of a semiconductor device according to the invention and a manufacturing method of the semiconductor device. In a semiconductor device 103 of the present embodiment, an electrode 22 formed on wiring 16 is formed in a post shape by plating. A form, in which a semiconductor element 14 is built into a resin molded part 12 and the semiconductor element 14 is connected to an electrode 16a by flip chip bonding and an outer surface of the wiring 16 is exposed flush with a lower surface which is one surface of the resin molded part 12, is similar to the first embodiment. An end face of a copper post 22a of the electrode 22 is covered with gold plating 22b and the top of the electrode 22 protrudes from an outer surface of the resin molded part 12.

FIGS. 5B to 5C show a manufacturing step of the semiconductor device 103 comprising the electrode 22.

FIG. 5B shows a state in which the gold plating 22b is performed on a surface of the copper post 22a. After the wiring 16 is formed on a surface of a metal substrate 30 in a predetermined pattern, the surface of the metal substrate 30 is covered with a resist 40. A recessed hole 42 is formed on the resist 40 in a region for forming the electrode 22 on the wiring 16 by light exposure and development operations. Copper plating is deposited in the recessed hole 42 by electrolytic copper plating and the copper post 22a is formed. The gold plating 22b is further performed on a surface of the copper post 22a.

Since the copper post 22a is formed in a necessary height as the electrode 22, the resist 40 is formed somewhat thicker than the height of the copper post 22a. The recessed hole 42 is formed so that the wiring 16 is exposed to the inner bottom surface by performing the light exposure and development operations to the resist 40. The gold plating 22b is performed as protective plating of the copper post 22a, and could be formed in a thickness of the extent to which corrosion resistance can be obtained.

A method for forming the wiring 16 on the surface of the metal substrate 30 is similar to that in the first embodiment.

After the electrode 22 is formed, the resist 40 is dissolved and removed and subsequently, the semiconductor element 14 is mounted on the metal substrate 30. FIG. 5C shows a state of mounting the semiconductor element 14 by flip chip bonding. A method for mounting the semiconductor element 14 is not limited to the flip chip bonding in a manner similar to the description in the first embodiment.

Subsequently, the metal substrate 30 on which the semiconductor element 14 is mounted is clamped by resin molding metal molds 32a, 32b and a resin is molded. FIG. 5D shows a state of molding the resin. In the case of covering an inner surface of a cavity formed in the resin molding metal mold 32a with a film 34 for resin molding and clamping work, the resin is molded so that the top of the electrode 22 is sunk in the film 34. The top of the electrode 22 sinks in the film 34. Therefore, the resin can be molded without attaching a resin 12a to the top of the electrode 22 and the resin is molded in a state in which the top of the electrode 22 is exposed to the outer surface of the resin molded part 12 and is protruded.

The semiconductor device 103 shown in FIG. 5A is obtained by dissolving and removing the metal substrate 30 after the resin is molded.

In the semiconductor device 103 of the embodiment, an electrical resistance value of the electrode 22 can be decreased by forming the electrode 22 by the copper post.

### Third Embodiment

FIGS. 6A to 6D show a configuration of a third embodiment of a semiconductor device according to the invention and a manufacturing method of the semiconductor device. In a semiconductor device 104 of the present embodiment, an electrode 23 is formed by folding a wire. A configuration etc. in which a semiconductor element 14 is built into a resin molded part 12 are similar to those of each of the embodiments described above.

The electrode 23 formed in the semiconductor device 104 of the embodiment is disposed so that a metal wire is folded in a chevron shape (loop shape) and is erected on wiring 16. The top of the electrode 23 folded in the chevron shape protrudes from an outer surface of the resin molded part 12 as shown in FIG. 6A.

FIGS. 6B to 6C show a manufacturing method of the semiconductor device 104 of the embodiment.

FIG. 6B shows a state of forming the electrode 23 on the wiring 16 after the wiring 16 is formed on a surface of a metal substrate 30 in a predetermined pattern. The electrode 23 can be formed by a wire bonding method. For example, a gold wire is used as a metal wire, and after one end of the gold wire is bonded on the wiring 16, the tip of a capillary is moved in a chevron-shaped loop shape and the other end is bonded on the wiring 16. Therefore, the electrode 23 can be formed in the chevron shape as shown in FIG. 6B. In the wire bonding method, a form or a height of a loop can be adjusted and the electrode 23 can be formed by setting a bonding condition so as to become a loop (chevron shape) with a predetermined height.

FIG. 6C shows a state of mounting the semiconductor element 14 on the metal substrate 30 on which the electrode 23 is formed by flip chip bonding. Bumps 19 formed on the semiconductor element 14 are aligned with electrodes 16a of the wirings 16 and are bonded to the electrodes 16a.

In addition, in the case of mounting the semiconductor element 14 on the metal substrate 30 by wire bonding, the electrode 23 can also be formed in the same step when connection between the semiconductor element 14 and the electrodes 16a of the wirings 16 is made by wire bonding after the semiconductor element 14 is bonded on the metal substrate 30. In this case, there is an advantage capable of efficiently performing a step of forming the electrode 23.

FIG. 6D is a state in which the metal substrate 30 on which the electrode 23 is formed and the semiconductor element 14 is mounted is clamped by resin molding metal molds 32a, 32b and a resin is molded. In a manner similar to the embodiments described above, an inner surface of a cavity of the resin molding metal mold 32a is covered with a film 34 for resin molding and the top of the electrode 23 is sunk in the film 34 and the resin is molded.

Consequently, the top of the electrode 23 protrudes from an outer surface of the resin molded part 12 in a state of being exposed and the resin is molded. The semiconductor device 104 shown in FIG. 6A is obtained by removing the metal substrate 30 after the resin is molded.

### Fourth Embodiment

FIGS. 7A to 7D show a configuration of a fourth embodiment of a semiconductor device according to the invention and a manufacturing method of the semiconductor device. In, a semiconductor device 105 of the present embodiment, a conductive ball body in which a conductive material such as copper is deposited on a surface of a resin core formed in a spherical shape or a copper ball is used as an electrode 24.

As shown in FIG. 7A, in the semiconductor device 105 of the embodiment, the electrode 24 formed by the conductive ball body is bonded to wiring 16 and an upper part of the electrode 24 is exposed to the outside and is protruded from an outer surface of a resin molded part 12. The other configuration of the semiconductor device 105 is similar to the semiconductor device of each of the embodiments described above.

FIGS. 7B to 7D show a manufacturing method of the semiconductor device 105 according to the invention. After the electrode 24 is bonded to a metal substrate 30 on which the wiring 16 of a predetermined pattern is formed as shown in FIG. 7B, a semiconductor element 14 is mounted on the metal substrate 30 by flip chip bonding as shown in FIG. 7C. In addition, in a step of bonding the electrode 24 to the wiring 16 and a step of mounting the semiconductor element 14 on the metal substrate 30, order of the steps can be reversed. The same applies to the other embodiments described above.

After the electrode 24 is bonded to the metal substrate 30 and the semiconductor element 14 is mounted, the metal substrate 30 is clamped by resin molding metal molds 32a, 32b and a resin is molded as shown in FIG. 7D. In this resin molding step, the resin is molded so that an upper part of the electrode 24 is partially sunk in a film 34 for resin molding and a resin 12a for molding does not infiltrate into an outer surface of the electrode 24.

The semiconductor device 105 shown in FIG. 7A is obtained by removing the metal substrate 30 after the resin is molded.

The semiconductor device 105 of the embodiment has an advantage capable of aligning a height of the electrode 24 with high accuracy by using the conductive ball body such as a solder ball in the electrode

### Fifth Embodiment

FIG. 8A shows a configuration of a fifth embodiment of a semiconductor device according to the invention. In a semiconductor device 106 of the present embodiment, two semiconductor elements 14a, 14b are stacked and mounted. Each of the semiconductor elements 14a, 14b is electrically connected to wiring 16 by wire bonding, and an electrode 20 and bonding wires 50 are sealed with a resin molded part 12. An outer surface of the wiring 16 is exposed flush with an outer surface of the resin molded part 12.

In a manner similar to the first embodiment, the electrode 20 is formed by ball bonding and a tip part 20a of the electrode 20 protrudes in a state of being exposed to the outside of the resin molded part 12.

FIG. 8B shows a state of molding a resin by clamping work by resin molding metal molds 32a, 32b in a manufacturing step of the semiconductor device 106 of the embodiment. The semiconductor elements 14a, 14b are bonded and supported to a metal substrate 30 by an adhesive layer 52 and also the portion between the semiconductor elements is bonded.

By partially sinking the tip part 20a of the electrode 20 in a film 34 for resin molding and molding a resin, the tip part 20a is protruded in a state of being exposed to an outer surface of the resin molded part 12 and the resin can be molded. The semiconductor device 106 shown in FIG. 8A is obtained by dissolving and removing the metal substrate 30 after the resin is molded.

In addition, the three or more semiconductor elements can be stacked and mounted. Also, a composite mounting method in which the semiconductor element 14a of the lower side is mounted by flip chip bonding and the semiconductor element 14b of the upper side is mounted by wire bonding can be used. Also, the electrodes 22, 23, 24 used in each of the embodiments can be adopted as an electrode instead of the electrode 20 by ball bonding.

### Sixth Embodiment

FIG. 9A shows a configuration of a sixth embodiment of a semiconductor device according to the invention. A semiconductor device 107 of the present embodiment is characterized by having a form in which a bonding wire for connecting a semiconductor element 14 to wiring 16 is shared with an electrode 25.

In FIG. 9A, the semiconductor element 14 is connected to the wiring through a bonding wire 25a, and wire bonding is performed in a form of folding the bonding wire 25a in a chevron shape (loop shape) and the electrode 25 is formed by the bonding wire 25a. The electrode 25 is formed with the upper part exposed to an outer surface of a resin molded part 12 in a manner similar to the semiconductor device of each of the embodiments described above.

In addition, the wiring 16 is exposed to the outer surface (lower surface) of the resin molded part 12. The wiring 16 is formed so that plane arrangement positions of the wiring 16 and the electrode 25 overlap so as to electrically connect semiconductor devices of the upper and lower sides through the electrode 25 in the case of stacking the semiconductor devices 107.

FIG. 9B shows a state of molding a resin by clamping work by resin molding metal molds 32a, 32b in a manufacturing step of the semiconductor device 107 of the embodiment. A situation in which the semiconductor element 14 is bonded and supported to a metal substrate 30 by an adhesive layer 52 and an upper part of the electrode 25 sinks in a film 34 for resin molding and a resin is molded is shown.

Consequently, the upper part of the electrode 25 is exposed to the outer surface of the resin molded part 12 and the upper part of the electrode 25 is slightly protruded from the outer surface of the resin molded part 12 and the resin can be molded. The semiconductor device 107, in which an outer surface of the wiring 16 is exposed flush with the outer surface (lower surface) of the resin molded part 12, is obtained by dissolving and removing the metal substrate 30 after the resin is molded.

### Seventh Embodiment

FIGS. 10A and 10B show a configuration of a seventh embodiment of a semiconductor device according to the invention. A semiconductor device 108 of the present embodiment is characterized by being constructed so that bumps 19 formed on a semiconductor element 14 are used for connection between semiconductor devices in addition to an electrode 20 formed by ball bonding.

That is, when the semiconductor element 14 is built into a resin molded part 12, a resin ins molded so that the semiconductor element 14 is arranged so as to set the bumps 19 of the semiconductor element 14 in a direction of protruding from an outer surface (upper surface) of the resin molded part 12 and tip parts 19a of the bumps 19 are protruded from the outer surface of the resin molded part 12. In the resin molded part 12, a tip part 20a of the electrode 20 protrudes to the upper surface and also the tip parts 19a of the bumps 19 of the semiconductor element 14 protrude and an outer surface of a wiring 16 is exposed flush with an outer surface (a lower surface) of the resin molded part 12.

FIG. 10B shows a method for forming the semiconductor device 108 of the embodiment. The semiconductor element 14 is supported on a metal substrate 30 with the back surface (surface opposite to the surface on which the bumps 19 are formed) bonded by an adhesive layer 52 and is clamped by resin molding metal molds 32a, 32b in a state of setting the bumps 19 upward. In the case of clamping work by the resin molding metal molds 32a, 32b, the tip part 20a of the electrode 20 and the tip parts 19a of the bumps 19 are sunk in a film 34 for resin molding and a cavity is filled with a resin 12a. Therefore, the tip part 20a of the electrode 20 and the tip parts 19a of the bumps 19 are protruded from the outer surface of the resin molded part 12 and the resin can be molded.

The semiconductor device 108 shown in FIG. 10A is obtained by dissolving and removing the metal substrate 30 after the resin is molded.

### (Example of Assembly of Semiconductor Devices)

FIGS. 11 and 12 show examples of assembly of semiconductor devices formed by stacking the semiconductor devices shown in each of the embodiments described above.

FIG. 11A is an example formed by stacking the two semiconductor devices 100 shown in FIG. 1A, and FIG. 11B is an example formed by stacking the three semiconductor devices 100. A tip part 20a of an electrode 20 protrudes to an outer surface of a resin molded part 12 of the semiconductor device 100. Therefore, the electrode 20 formed in the semiconductor device 100 of the lower side and wiring 16 of the semiconductor device 100 of the upper side abut and are electrically connected by stacking the semiconductor devices 100 through an adhesive layer 60 between the devices.

As the adhesive layer 60, a layer made of a mere insulating material, a layer made of an anisotropic conductive resin, etc. can be used. In the case of being bonded by the adhesive layer 60 made of the insulating material, bonding is performed so that the tip part 20a of the electrode 20 surely abuts on the wiring 16 of the semiconductor device 100 of the upper side. In the case of using the adhesive layer 60 made of the anisotropic conductive resin, the wiring 16 is electrically connected selectively to a region in which the tip part 20a of the electrode 20 is formed.

The wiring 16 and the electrode 20 disposed in the semiconductor device 100 are set in arrangement in which the plane arrangement positions overlap as shown in FIGS. 11A and 11B. Therefore, the semiconductor devices 100 are assembled in a state in which the semiconductor devices mutually make contact between the devices and are electrically connected by aligning and stacking the semiconductor devices 100.

FIGS. 11A and 11B are the examples stacked with the semiconductor devices 100 set in the same direction, but FIG. 11C is an example assembled by stacking the semiconductor devices 100 in a reverse direction, that is, with tip parts 20a of electrodes 20 of the semiconductor devices 100 of the upper side and the lower side opposed. In this case, the tip parts 20a of the electrodes 20 of the semiconductor devices 100 of the upper side and the lower side abut and are electrically connected.

FIG. 12A is an example assembled by stacking the semiconductor devices 104 shown in FIG. 6A. An electrode 23 is obtained by forming a wire in a chevron-shaped loop shape and an upper part of the wire formed in the chevron shape protrudes from a resin molded part 12. Therefore, the semiconductor devices 104 are assembled in a state in which a protrusion part of the electrode 23 abuts on (makes contact with) wiring 16 of the upper side and is mutually electrically connected to the wiring 16 by stacking the semiconductor devices 104.

FIG. 12B is an example assembled by stacking the semiconductor devices 108 shown in FIG. 10A. In the semiconductor devices 108, an electrode 20 abuts on wiring 16 of the upper side and is electrically connected to the wiring 16 and also a semiconductor element 14 of the upper side is mutually electrically connected to a semiconductor element 14 of the lower side by the bump 19 in the case of stacking the semiconductor devices 108.

According to the semiconductor device according to the invention as shown in FIGS. 11A to 12B, the tip part of the electrode is formed by protruding the tip part to the outer surface of the resin molded part 12 of the semiconductor device. Therefore, electrical continuity between the mutual semiconductor devices is simply obtained by only stacking the semiconductor devices and assembly can be performed and assembly work is facilitated. Further, the semiconductor device can be formed compactly in a thin shape even in the case of stacking the semiconductor devices by being formed in a form in which the semiconductor element 14 is built into the resin molded part 12 formed in a flat plate shape.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A semiconductor device comprising:
a resin molded part molded in a flat plate shape;
a semiconductor element built into the resin molded part;
a wiring, which is electrically connected to the semiconductor element and is disposed on one surface of the resin molded part so that an inner surface side of the wiring is sealed with the resin molded part and an outer surface of the wiring is exposed flush with the one surface of the resin molded part; and
an electrode, which is disposed on the wiring in an outside of a plane area of the semiconductor element and extends through the resin molded part in a thickness direction, the electrode having a tip part which protrudes from the other surface of the resin molded part.

2. A semiconductor device as claimed in claim 1, wherein the semiconductor element is electrically connected to the wiring by flip chip bonding, and a back surface of said semiconductor element is exposed flush with the other surface of the resin molded part.

3. A semiconductor device as claimed in claim 1, wherein the semiconductor element is electrically connected to the wiring by flip chip bonding, and the electrode is arranged in a lead end of the wiring led from an inside of the plane area of the semiconductor element to the outside.

4. A semiconductor device as claimed in claim 1, wherein the semiconductor element is electrically connected to the wiring by wire bonding.

5. A semiconductor device as claimed in claim 1, wherein a plurality of the semiconductor elements are stacked and built into the resin molded part.

6. A semiconductor device as claimed in claim 1, wherein the electrode is formed as a ball bump formed by a ball bonding method.

7. A semiconductor device as claimed in claim 6, wherein a plurality of the ball bumps are formed and stacked.

8. A semiconductor device as claimed in claim 1, wherein the electrode is formed in a post shape by plating.

9. A semiconductor device as claimed in claim 1, wherein the electrode is formed by a metal wire folded in a chevron-shaped loop shape by a wire bonding method.

10. A semiconductor device as claimed in claim 1, wherein the electrode is formed by a conductive ball body bonded to the wiring.

11. A semiconductor device comprising:
a resin molded part molded in a flat plate shape;
a semiconductor element built into the resin molded part;
a wiring, which is disposed on one surface of the resin molded part so that an inner surface side of the wiring is sealed with the resin molded part and an outer surface of the wiring is exposed flush with the one surface of the resin molded part;
an electrode, which is disposed on the wiring in an outside of a plane area of the semiconductor element and extends through the resin molded part in a thickness direction, the electrode having a tip part which protrudes from the other surface of the resin molded part; and
a bump, which is disposed in the semiconductor element built into the resin molded part and protrudes from the other surface of the resin molded part.

12. A semiconductor device product comprising:
a plurality of semiconductor devices as claimed in claim 1, which are stacked in the same direction and are integrated,
wherein a wiring of one semiconductor device of adjacent devices makes contact with a tip part of an electrode of the other semiconductor device of the adjacent devices to achieve electrical continuity between the semiconductor devices.

13. A semiconductor device product comprising:
a plurality of semiconductor devices as claimed in claim 1, which are stacked in a direction of opposing tip parts of electrodes of adjacent devices and are integrated,
wherein the tip parts of the electrodes are mutually abutted to achieve electrical continuity between the semiconductor devices.

14. A semiconductor device product comprising:
a plurality of semiconductor devices as claimed in claim 11, which are stacked in the same direction and are integrated,
wherein a wiring of one semiconductor device of adjacent devices makes contact with a tip part of an electrode of the other semiconductor device of the adjacent devices to achieve electrical continuity between the semiconductor devices, and
wherein electrical continuity between the adjacent devices is also achieved by the bump.

15. A manufacturing method of a semiconductor device, comprising steps of:
forming a wiring on a metal substrate in a predetermined pattern;
mounting a semiconductor element on the metal substrate and electrically connecting the semiconductor element to the wiring;
forming an electrode on the wiring;
molding a resin by a resin molding metal mold having a cavity, which accommodates the semiconductor element, the wiring and the electrode, by filling the cavity with the resin and sealing the semiconductor element, the wiring and the electrode with the resin; and
removing only the metal substrate after the resin is molded,
wherein when the resin is molded by the resin molding metal mold, an inner surface of the cavity is covered with a film for resin molding and the cavity is filled with the resin in a state of sinking a tip part of the electrode in the film and the resin is molded without attaching the resin to the tip part.

16. A manufacturing method of a semiconductor device as claimed in claim 15, wherein when the resin is molded by the resin molding metal mold, the inner surface of the cavity is covered with the film for resin molding and the cavity is filled with the resin in a state of sinking the tip part of the electrode in the film and bringing the film into pressure contact with a back surface of the semiconductor element and the resin is molded without attaching the resin to the tip part and the back surface of the semiconductor element.

17. A manufacturing method of a semiconductor device as claimed in claim 15, wherein only the metal substrate is selectively chemically dissolved and removed without eroding the wiring when the metal substrate is removed after the resin is molded.
